(19) United States
(12) Patent Application Publication
(10) Pub. No.: US 2019/0057838 A1
(43) Pub. Date: Feb. 21, 2019

(54) METHOD FOR ELECTRONIC LITHOGRAPHY WITH ELECTROSTATIC SCREENING

(71) Applicant: COMMISSARIAT A L'ENERGIE ATOMIQUE ET AUX ENERGIES ALTERNATIVES, PARIS (FR)

(72) Inventors: Ludovic LATTARD, COUBLEVIE (FR); Patrick QUEMERE, VOREPPE (FR)

(21) Appl. No.: 16/078,624

(22) PCT Filed: Feb. 20, 2017
(86) PCT No.: PCT/EP2017/053749

§ 371 Date: Aug. 21, 2018

(30) Foreign Application Priority Data
Feb. 25, 2016 (FR) 1651541

(51) Int. Cl. H01J 37/317; H01L 21/027; H01L 21/311

(52) U.S. Cl. CPC H01J 37/3174; H01J 2237/31777; H01L 21/31144; H01L 21/027

(57) ABSTRACT

An e-beam lithography process includes the following steps: implanting into a substrate, or into a dielectric layer deposited on the surface of the substrate, electrons in a first pattern; depositing an e-beam resist on the surface of the substrate or of the sacrificial dielectric layer; and exposing the resist by means of an electron beam in a second pattern, then developing the resist; the first and second patterns being made up of elementary patterns, the elementary patterns of the first pattern at least partially surrounding the elementary patterns of the second pattern.

The invention relates to an e-beam lithography process and more particularly to a low-energy e-beam lithography process.

E-beam lithography (or “electron-beam lithography”) is a micro- and nano-fabrication process that consists in depositing a resist on the surface of a substrate, in exposing the resist to an electron beam so as to cause therein localized chemical and physical modifications, then in developing the resist, i.e. selectively removing its exposed portions (a “positive” resist is then spoken of) or unexposed portions (“negative” resist) in order to lay bare the subjacent regions of the substrate. A geometric pattern is therefore transferred to the resist by the electron beam; it may subsequently be transferred to the substrate through the apertures produced in the resist layer.

With respect to photolithography, e-beam lithography allows higher resolutions to be achieved, because diffraction effects are much less pronounced. Specifically, in e-beam lithography resolution is mainly limited by scattering of electrons in the resist and their backscatter by the substrate. The point spread function (PSF) allows these effects to be quantified; it is typically expressed by the following equation:

$$PSF ( r ) = \frac{1}{π ( 1 + η )} \{ \frac{1}{{α}^{2}} \cdot {e}^{- {r}^{2} \text{/} {α}^{2}} + \frac{η}{{β}^{2}} \cdot {e}^{- {r}^{2} \text{/} {β}^{2}} \}$$

where:
r is the radial distance with respect to the point of impact of the electron beam;
α is the standard deviation of the distribution (assumed Gaussian) of forward-scattered electrons;
β is the standard deviation of the distribution (assumed Gaussian) of electrons backscattered by the substrate; and
η is the proportion of electrons backscattered.

For example, it may be that α=17 nm, β=288.3 nm and η=0.35.

To minimize the spread of the PSF, electron beams of energy comprised between 50 keV and 100 keV are generally used. However, the use of such high energies causes heating, and therefore thermal deformation, of the substrate. This adversely affects the precision of the transfer of the geometric pattern. To avoid this effect, it has been proposed to use low-energy electrons—typically of 5 to 10 keV—that nevertheless have a sufficient penetration depth (of about 300 nm). However, under these conditions, the electrons undergo a substantial amount of scattering, this limiting the achievable spatial resolution.

It has also been proposed, in order to decrease the spread of the PSF, to insert an intermediate layer of low atomic density between the resist and the substrate, see for example document FR 2 994 489.

The invention aims to remedy the aforementioned drawbacks of the prior art. More particularly, it aims to improve the spatial resolution of e-beam lithography, and in particular of low-energy e-beam lithography.

According to the invention, this aim is achieved by virtue of prior implantation of electrons into the substrate—or into a dielectric layer deposited on its surface. These electrons are spatially distributed so as to generate a repulsive electric field that opposes the scattering of the electrons used in the actual lithography step.

One subject of the invention is therefore an e-beam lithography process comprising the following steps:

implanting into a substrate, or into a dielectric layer deposited on the surface of said substrate, electrons in a first pattern;

depositing an e-beam resist on the surface of said substrate or of said sacrificial dielectric layer; and

exposing said resist by means of an electron beam in a second pattern, then developing said resist;

said first and second patterns being made up of elementary patterns, the elementary patterns of said first pattern at least partially surrounding the elementary patterns of said second pattern.

Other features, details and advantages of the invention will become apparent on reading the description given with reference to the appended drawings, which are given by way of example and show, respectively:

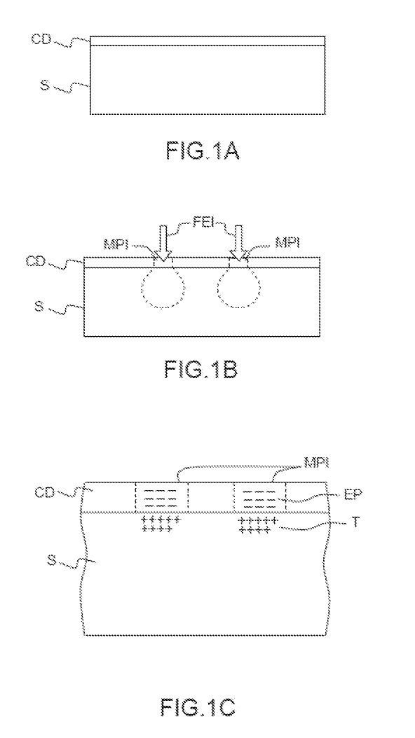

FIGS. 1A to 1F, six steps of a process according to one embodiment of the invention;

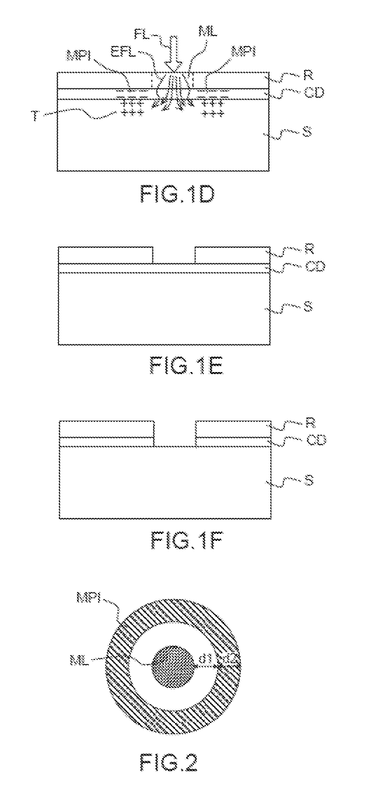

FIG. 2, an example of a geometric lithography pattern, and of the prior electron implantation pattern that is associated therewith; and

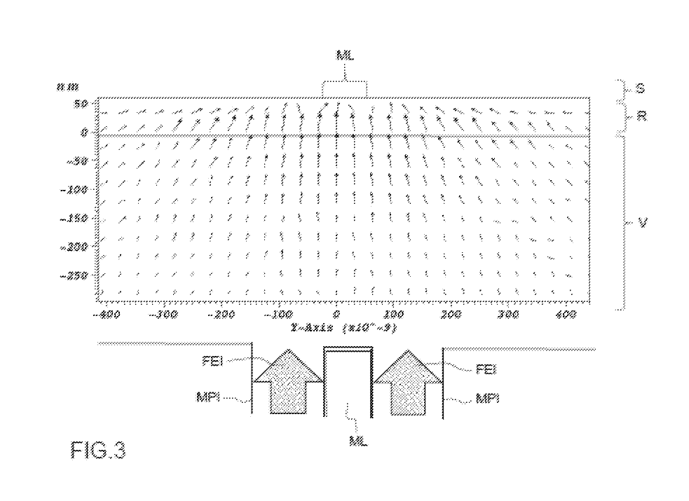

FIG. 3 illustrates the electric field obtained by virtue of the electron implantation prior to the lithography.

The figures are not to scale.

FIG. 1A shows a semiconductor substrate S, which for example is made of silicon, on which is deposited a sacrificial layer (i.e. a layer that is intended to be removed) CD made of a dielectric—for example of silicon oxide, a metal oxide, titanium nitride, etc. The thickness of this layer CD is typically about a few tens of nanometers, for example comprised between 10 and 100 nm and preferably between 20 and 50 nm. Its resistivity is preferably higher than or equal to 10⁶ Ω/▪ (ohms/square). If the substrate is insulating, the layer CD may be absent.

Electrons are implanted in the layer CD by means of an electron beam FEI, in an elementary geometric pattern MPI the characteristics of which will be discussed below. This step is illustrated in FIG. 1B, in this particular embodiment, the elementary pattern MPI is ring shaped. A fraction of the electrons of the beam FEI are trapped in the dielectric, the others scattering into the semiconductor substrate, which is connected to ground. The scattering clouds of the electrons have been shown by dashed lines in the figure. The implantation dose in the layer CD, which is defined as the incident charge density, is generally comprised between 1 and 100 μC/cm²; preferably this dose is deposited at very low energy (less than 5 keV) in order to maximize the number of electrons that remain trapped in the dielectric. FIG. 1C schematically shows the electrons EP trapped in the dielectric layer CD; it may be seen therein that the implantation pattern MPI has been transferred to the dielectric layer in the form of a negative charge density. It will also be noted that holes T, which are attracted by the trapped electrons ED, accumulate in the substrate, in proximity to the interface with the dielectric layer.

Next, as illustrated in FIG. 1D, a layer of resist R is deposited on the dielectric layer CD, then this resist is exposed to an electron beam FL, preferably a low-energy electron beam (10 keV or less, or even 5 keV or less), in an elementary geometric lithography pattern ML. In the example of the figure, the elementary pattern ML takes the form of a circular disk located in the interior of the ring-shaped prior implantation pattern MPI; these two patterns are illustrated in FIG. 2. More generally, the elementary prior implantation pattern MPI surrounds the lithography pattern. If the latter takes the form of a linear track for example, the pattern MPI will consist of two other linear tracks, located on either side of the first.

It may be seen in FIG. 1D that the electrons EFL of the lithography beam FL are repulsed by the electrons EP trapped in the layer CD, this having the effect of confining them to the interior of the lithography pattern ML, limiting scatter thereof. FIG. 3 shows the electrostatic field in free space V, above the layer of resist R. It will be noted that the electric field converges toward the center of the pattern ML.

After they have passed through the layer, the electrons EFL reach the substrate, where they rapidly recombine with the holes T accumulated at the substrate-dielectric layer interface. This rapid recombination decreases the fraction η of backscattered electrons and therefore contributes to limiting the spread of the PSF. This effect does not occur if the substrate is insulating.

The implanted charge dose and the geometry of the implantation pattern MPI may be optimized by means of numerical simulations taking into account the scattering of the electrons EFL in the resist and in the substrate, and the influence of the electric field generated by the trapped electrons EP and the holes T. In the case of a disk-shaped elementary lithography pattern ML and of an implantation pattern MPI of circular annulus shape, there are only three parameters to be optimized: the implanted dose, the spacing between the pattern ML and the pattern MPI (shown by d1 in FIG. 2) and the width of the circular annulus MPI (d2). Trials may therefore be carried out to easily achieve this optimization.

The subsequent steps of the process are conventional: the exposed resist is developed, so as to obtain an aperture in correspondence with the lithography pattern ML—if the resist is positive—or its complement—if the resist is negative (FIG. 1E), then, or at the same time, the sacrificial dielectric layer CD (FIG. 1F) is etched so as to lay bare the substrate S. It is then possible to proceed, for example, to deposit a metallization on the surface of the substrate, in correspondence with the aperture thus obtained (not shown).

Of course, in actual applications the implantation pattern and the lithography pattern will be made up of a large number of elementary patterns such as those shown in the figures.

1. An e-beam lithography process comprising the following steps:
implanting into a substrate, or into a dielectric layer deposited on the surface of said substrate, electrons in a first pattern;
depositing an e-beam resist on the surface of said substrate or of said sacrificial dielectric layer; and
exposing said resist by means of an electron beam in a second pattern, then developing said resist;
said first and second patterns being made up of elementary patterns, the elementary patterns of said first pattern at least partially surrounding the elementary patterns of said second pattern.

2. The process as claimed in claim 1, also comprising a prior step of depositing said dielectric layer on the surface of said substrate, and a step of etching the regions of said dielectric layer that are exposed following the development of the resist.

3. The process as claimed in claim 2, wherein said dielectric layer has a thickness comprised between 10 and 100 nm and preferably between 20 and 50 nm.

4. The process as claimed in claim 2, wherein said dielectric layer has a resistivity higher than or equal to 10⁶ Ω/▪.

5. The process as claimed in claim 2, wherein said substrate is a semiconductor substrate.

6. The process as claimed in claim 1, wherein said resist is exposed by means of an electron beam of energy lower than or equal to 10 keV and preferably 5 keV.

7. The process as claimed in claim 1, including implanting a charge density comprised between 1 and 100 μC/cm² into said substrate or said dielectric layer.

8. The process as claimed in claim 1, including a prior step of optimizing said first pattern so that the electric field generated by the implanted electrons concentrates the electron beam used to expose the resist in the interior of the elementary patterns of said second pattern
